(19) United States
(12) Patent Application Publication
(10) Pub. No.: US 2005/0272210 A1
(43) Pub. Date: Dec. 8, 2005

(54) Method for manufacturing gate electrode of semiconductor device using aluminium nitride film

(75) Inventors: Tae Hyeok Lee, Gyeonggi-do (KR); Jun Soo Chang, Gyeonggi-do (KR); Dong Su Park, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 10/998,968

(22) Filed: Nov. 30, 2004

(30) Foreign Application Priority Data
Jun. 8, 2004 (KR) 10-2004-0041806

(51) Int. Cl. H01L 21/8238

(52) U.S. Cl. 438/287

(57) ABSTRACT

A method for manufacturing gate electrode of semiconductor device using an aluminium nitride film is provided, the method including cleaning a surface of a semiconductor substrate, nitriding the surface of the substrate, forming a gate dielectric film comprising an aluminium nitride film on the surface of a semiconductor substrate, depositing a gate conductive layer and a hard mask layer on the gate dielectric film, and etching the hard mask layer, the gate conductive layer, the gate dielectric film to form a gate electrode.

### BACKGROUND OF THE INVENTION

1. Field of the Invention

The present invention generally relates to method for manufacturing gate electrode of semiconductor device using an aluminium nitride film, and more specifically to method for manufacturing gate electrode of semiconductor device using an aluminium nitride film wherein an aluminium nitride film is used as a gate dielectric film, thereby decreasing an Equivalent Oxide Thickness (“EOT”) of the gate dielectric film and improving the operation speed and power consumption characteristics of a semiconductor device.

2. Description of the Related Art

FIG. 1 illustrates a conventional method for manufacturing gate electrode of semiconductor device.

Referring to FIG. 1, a gate dielectric film 20 comprising a silicon oxide layer is formed on a semiconductor substrate 10. Next, a stacked structure of a polysilicon layer 30, a tungsten silicide layer 40, and a hard mask layer (not shown) is deposited on the gate dielectric film 20. The stacked structure is then patterned to form a gate electrode.

In the aforementioned conventional method for forming a gate electrode, leakage current is induced due to a low dielectric constant (i.e. 3.85) of the gate dielectric film. As a result, the EOT cannot be reduced to below 50 Å.

In addition, the tungsten silicide layer and a tungsten layer used as gate electrode react with a silicon oxide layer in a thin film deposition process and a subsequent annealing process to deteriorate the electrical characteristic of the gate dielectric film.

### SUMMARY OF THE INVENTION

Accordingly, it is an object of the present invention to provide a method for manufacturing gate electrodes of a semiconductor device wherein an aluminium nitride film is used as a gate dielectric film so as to reduce the EOT and the stress generated in an annealing process of the gate dielectric film.

Moreover, it is another object of the present invention to provide a method for manufacturing gate electrodes of a semiconductor device wherein the structure of the gate electrode is simplified and Rs of a word line is reduced by performing the gate dielectric film from reacting with a gate conductive layer such as a tungsten-silicide layer and a tungsten layer to improve the operation speed and power consumption characteristics of a semiconductor device.

In order to achieve above-described object, there is provided a method for a method for manufacturing gate electrode of semiconductor device using an aluminium nitride film, the method comprising the steps:
(a) cleaning a surface of a semiconductor substrate;
(b) forming a gate dielectric film comprising an aluminium nitride film on the surface of a semiconductor substrate;
(c) depositing a gate conductive layer and a hard mask layer on the gate dielectric film; and
(d) etching the hard mask layer, the gate conductive layer, the gate dielectric film to form a gate electrode.

### BRIEF DESCRIPTION OF THE DRAWINGS

FIG. 1 illustrates a conventional method for forming gate electrode of semiconductor device.

FIGS. 2a through 2e illustrate a method for manufacturing gate electrode of semiconductor device using aluminium nitride film according to the present invention.

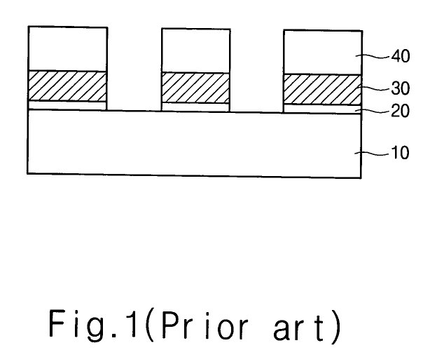

### DETAILED DESCRIPTION OF THE EXEMPLARY EMBODIMENTS

A method for manufacturing gate electrode of semiconductor device using aluminium nitride film will now be described in detail with reference to the accompanying drawings. Wherever possible, the same reference numerals will be used throughout the drawings to refer to the same or like parts.

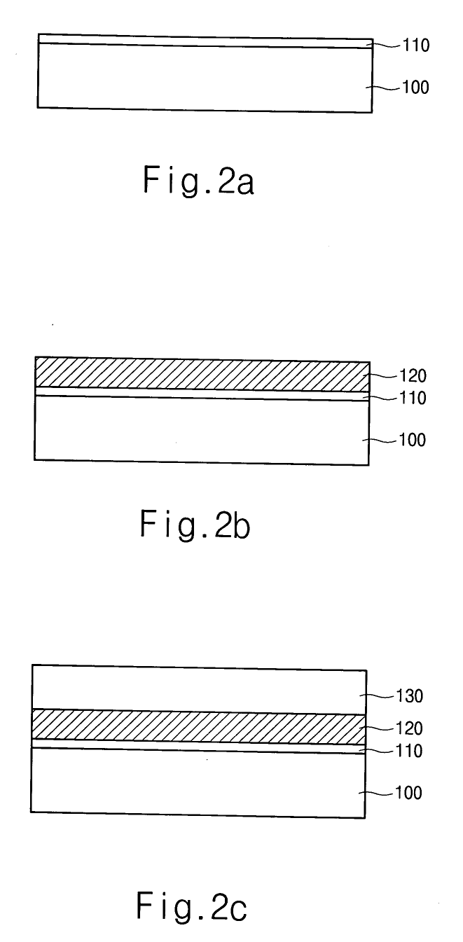

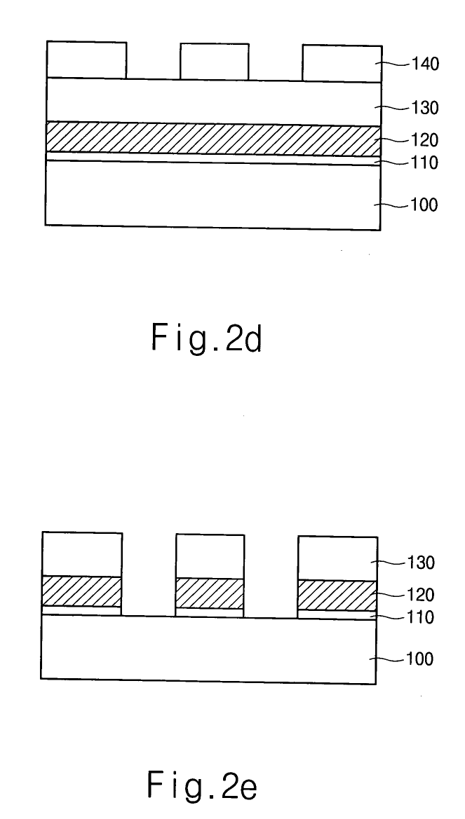

FIGS. 2a through 2e are cross-sectional views illustrating method for manufacturing gate electrode of semiconductor device using an aluminium nitride film as a gate dielectric film according to an embodiment of the present invention.

As a preparation process, a cleaning process is performed to clean a surface of a semiconductor substrate 100. Preferably, the cleaning process comprises a wet cleaning process using a HF solution or a dry cleaning process using HF vapor.

Preferably, the surface of the semiconductor substrate 100 may be subjected to a nitriding process so as to nitride the natural oxide film on the surface of the semiconductor substrate 100 after the cleaning process. The cleaning process and the nitriding process may be performed in-situ.

The nitriding process comprises a thermal treatment process performed in an atmosphere of a gas selected from the group consisting of NH₃, N₂O, NO, and combinations thereof. Preferably, the thermal treatment process is carried out using a plasma at a temperature ranging from 400° C. to 800° C. and a pressure ranging from 0.05 Torr to 760 Torr for 3 minute to 180 minute.

Now referring to FIG. 2a, a gate dielectric film 110 comprising an aluminium nitride film is formed on the surface of the semiconductor substrate 100 where an active region is to be formed.

Here, the thickness of the aluminium nitride film ranges from 30 Å to 300 Å. In accordance with one embodiment, the aluminium nitride film may be formed by nitriding an aluminium film using a gas selected from the group consisting of NH₃, NH₃+Ar and NH₃+N₂ at a temperature ranging from 400° C. to 800° C. and a pressure ranging from 0.01 Torr to 760 Torr. In accordance with another embodiment, the aluminium nitride film may be formed by performing an ALD method using a source containing Al and a nitriding gas of NH₃ and N₂ at a temperature ranging from 300° C. to 800° C. and a pressure ranging from 0.05 Torr to 50 Torr. The methods of above two embodiments can be combined to form the aluminium nitride film.

Preferably, a thermal treatment process may further be carried out after formation of the gate dielectric film 110. The thermal process may comprise a rapid heat treatment at a temperature ranging from 500° C. to 900° C. and a pressure ranging from 0.01 Torr to 760 Torr for 10 second to 7200 second or a plasma treatment at a temperature ranging from 300° C. to 700° C. for 10 second to 3600 second.

As shown in FIGS. 2b and 2c, a stacked structure of a polysilicon layer 120 and a gate conductive layer 130 is formed on the gate dielectric film 110.

Referring to FIGS. 2d and 2e, the gate conductive layer 130, the polysilicon layer 120, and the gate dielectric layer 110 are sequentially etched using a hard mask layer pattern 140 as an etching mask to form a gate electrode.

As described above, an aluminium nitride film is formed as a gate dielectric film in accordance with the present invention. The aluminium nitride film decreases the EOT and reduces the stress generated in an annealing process of the gate dielectric film since the aluminium nitride film has excellent etching tolerance and thermal expansion coefficient close to that of a silicon substrate.

In addition, due to high chemical stability of the aluminium nitride film, the aluminium nitride film does not react with a gate conductive layer such as a tungsten-silicide layer and a tungsten layer having a low resistivity. As a result, the structure of the gate electrode is simple and Rs of a word line is reduced, thereby enhancing the operation speed and power consumption characteristics of semiconductor device.

As the present invention may be embodied in several forms without departing from the spirit or scope thereof, it should also be understood that the above-described embodiment is not limited by any of the details of the foregoing description. Rather the present invention should be construed broadly as defined in the appended claims. All changes and modifications that fall within the metes and bounds of the claims, or equivalences of such metes and bounds are intended to be embraced by the appended claims.

1. A method for manufacturing gate electrode of semiconductor device using an aluminium nitride film, the method comprising the steps of:
(a) cleaning a surface of a semiconductor substrate;
(b) forming a gate dielectric film comprising an aluminium nitride film on the surface of a semiconductor substrate;
(c) depositing a gate conductive layer and a hard mask layer on the gate dielectric film; and
(d) etching the hard mask layer, the gate conductive layer, the gate dielectric film to form a gate electrode.

2. The method according to claim 1, wherein the cleaning process of the step (a) comprises a dry cleaning process or a wet cleaning process using HF.

3. The method according to claim 1, further comprising nitriding the surface of the substrate before the step (b).

4. The method according to claim 3, wherein the steps (a) and the nitriding process are performed in-situ.

5. The method according to claim 3, wherein the nitriding process comprises a thermal treatment process performed in an atmosphere of a gas selected from the group consisting of NH₃, N₂O, NO and combinations thereof.

6. The method according to claim 3, wherein the thermal treatment process is performed using a plasma at a temperature ranging from 400° C. to 800° C. and a pressure ranging from 0.05 Torr to 760 Torr for 3 minute to 180 minute.

7. The method according to claim 1, wherein the step (b) comprises a process selected from the group consisting of nitriding an aluminium film using a gas selected from the group consisting of NH₃, NH₃+Ar, and NH₃+N₂ at a temperature ranging from 400° C. to 800° C. and a pressure ranging from 0.01 Torr to 760 Torr, performing an Atomic Layer Deposition (ALD) method using a source containing Al and a nitride gas of NH₃ and N₂ at a temperature ranging from 300° C. to 800° C. and a pressure ranging from 0.05 Torr to 50 Torr, and combinations thereof.

8. The method according to claim 1, wherein the aluminium nitride film has a thickness ranging from 30 Å to 300 Å.

9. The method according to claim 1, the method further comprising performing a thermal treatment process after performing the step (b).

10. The method according to claim 9, wherein the thermal treatment process is performed at a temperature ranging from 500° C. to 900° C. and a pressure ranging from 0.01 Torr to 760 Torr for 10 second to 7200 second.

11. The method according to claim 9, wherein the thermal treatment process is performed using a plasma at a temperature ranging from 300° C. to 700° C. for 10 second to 3600 second.
